(19) United States
(12) Patent Application Publication
(10) Pub. No.: US 2026/0371987 A1
(43) Pub. Date: Nov. 19, 2026

(54) PROCESSING APPARATUS AND METHOD FOR COUPLING THE SAME

(71) Applicant: Taiwan Semiconductor Manufacturing Company, Ltd., Hsinchu (TW)

(72) Inventors: Chien Chou KO, Yongkang (TW); Chia Pao CHANG, Tainan (TW); Teng-Chia HUANG, Tainan (TW); Shih-Ming HUANG, Kaohsiung (TW)

(73) Assignee: Taiwan Semiconductor Manufacturing Company, Ltd., Hsinchu (TW)

(21) Appl. No.: 19/752,470

(22) Filed: Jul. 23, 2026

Related U.S. Application Data
(63) Continuation of application No. 18/784,610, filed on Jul. 25, 2024.

(51) Int. Cl. H10P 72/00; H10P 95/90

(52) U.S. Cl. CPC H10P 72/0431; H10P 72/0402; H10P 95/90

(57) ABSTRACT

A method of manufacturing a semiconductor device includes positioning a substrate on a hot plate in a chamber, and heating the substrate on the hot plate to volatilize contaminant particles on the substrate. The method further includes coupling the chamber to an external pump line through a locking mechanism. The locking mechanism is configured to couple a first adapter connecting to the chamber with a second adapter connecting to the external pump line. The method also includes detecting a coupling status between the first adapter and the second adapter using a sensor, and maintaining the locking mechanism based on the coupling status.

### RELATED APPLICATION

This application is a continuation of U.S. application Ser. No. 18/784,610 filed Jul. 25, 2024, the entire content of which is incorporated herein by reference.

### BACKGROUND

Size reduction of semiconductor devices has enabled continued improvement in speed, performance, density, and cost per unit function of integrated circuits and systems. As process nodes continue to shrink, critical dimensions (CD) of the semiconductor devices have approached and even surpassed the theoretical limits of photolithography equipment. An approach to achieve finer resolution with photolithographic equipment is to use a lithographic process to transfer the layout patterns of the photo mask onto the photoresist layer of the substrate such that etching, implantation, or other steps are applied to predefined regions of the substrate.

As the feature sizes are reduced and the critical dimensions drop to lower nanometers, the sensitivity of the photolithographic process to contaminant particles increases. For example, the contaminant particles have been observed in the track processes and these particles may become mobile and can cause image defocusing during the photoresist exposure process, resulting in blurred lines in the exposed photoresist and corresponding defects in the patterned devices. Lowered yield and increased cost for finished devices may therefore result. As such, advances in the field of extracting the contaminant particles from the track processes are necessary to reduce the maintenance time and improve the efficiency of the photolithographic process, and further improvements are needed in order to meet the desired design criteria such that the march towards smaller and smaller components may be maintained.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a block diagram of a wafer track system, according to embodiments of the disclosure.

FIG. 2 illustrates a processing apparatus for a process module, according to embodiments of the disclosure.

FIG. 3 illustrates a locking assembly for a processing apparatus, according to embodiments of the disclosure.

FIG. 4 illustrates a locking assembly for a processing apparatus, according to embodiments of the disclosure.

FIG. 5 illustrates a locking assembly for a processing apparatus, according to embodiments of the disclosure.

FIG. 6 illustrates a locking assembly for a processing apparatus, according to embodiments of the disclosure.

FIG. 7 illustrates a flow diagram of a method of manufacturing a semiconductor device, according to embodiments of the disclosure.

FIGS. 8A and 8B illustrate a computer system for controlling a method of manufacturing a semiconductor device according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Contaminant particles observed in the track processes may become mobile and cause image defocusing during the photoresist exposure process, resulting in blurred lines in the exposed photoresist and corresponding defects in the patterned devices. The contaminant particles may be reduced by providing suction to the track processes. However, unavoidable vibrations and/or movements of the track process apparatus may contribute to disengagement between the track processing apparatus and the external pump line, and cause the suction pressure to drop and the contaminant particles not to be efficiently removed. Embodiments of this disclosure provide an improved processing apparatus and methods of coupling the same, thereby reducing the maintenance time and improving the efficiency of the photolithographic process. In some embodiments, the improved processing apparatus includes a locking mechanism to couple the processing apparatus with an external pump line. In some embodiments, the improved processing apparatus includes a sensor to monitor and detect the coupling status between the processing apparatus and the external pump line.

In some embodiments of the present disclosure, a locking mechanism is applied to the processing apparatus. It will be understood by those skilled in the art that the disclosure could be applied to other apparatus where contaminant particles might be present in the process.

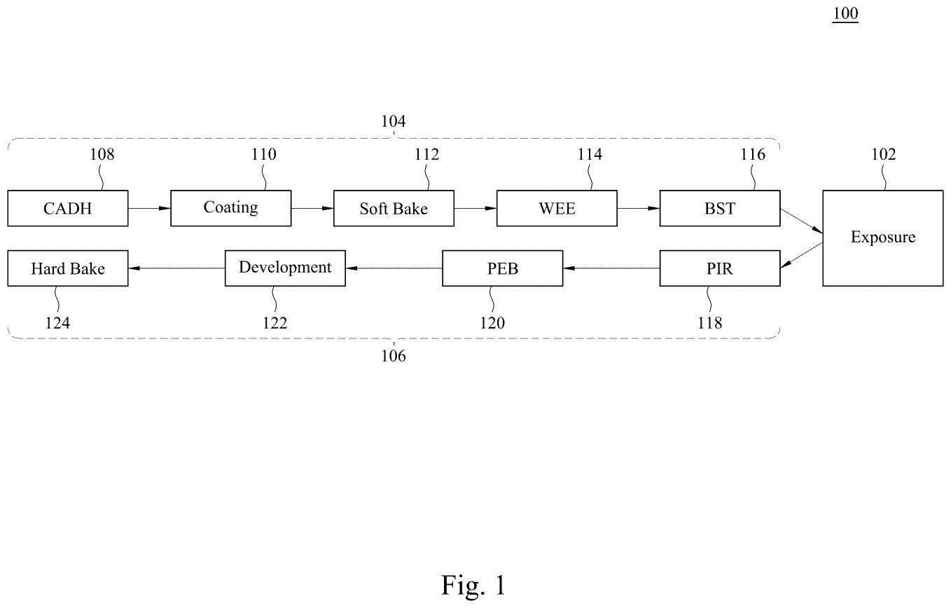

FIG. 1 illustrates a block diagram of a wafer track system according to embodiments of the disclosure. As shown in FIG. 1, the wafer track system 100 supports a spin-expose-develop processing sequence for patterning of a semiconductor wafer, according to embodiments of the disclosure. The wafer track system 100 may include an exposure device 102, one or more pre-processing modules 104, and one or more post-processing modules 106.

In some embodiments, the semiconductor wafer moves through the wafer track system 100 in the direction shown by the arrows in FIG. 1 to prepare for the exposure device 102 and to recover from exposure device 102, according to embodiments of the disclosure.

In some embodiments, the pre-processing modules 104 and the post-processing modules 106 serve to prepare the semiconductor wafers for processing in the various track modules. Because photoresist is a viscous liquid polymer, its properties can change with temperature. Therefore, characteristics of the photoresist can be optimized prior to, or after, processing at the spin/coat, exposure, and development modules.

In some embodiments, the semiconductor wafer includes any number of pre-formed layers. Materials on the semiconductor wafer may be patterned or may remain unpatterned. Furthermore, the semiconductor wafer can include one or more of a wide array of semiconductor materials including (i) an elementary semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Alternatively, the semiconductor wafer can be made from an electrically non-conductive material, such as a glass wafer, a sapphire wafer, or a plastic substrate. In some embodiments, the semiconductor wafer can be a bulk semiconductor wafer or the top semiconductor layer of a semiconductor-on-insulator (SOI) wafer (not shown). In some embodiments, the semiconductor wafer includes a crystalline semiconductor layer with its top surface, parallel to a (100), (110), (111), or c−(0001) crystal plane. The semiconductor wafer can be made of a semiconductor material such as, but is not limited to, silicon (Si). Further, the semiconductor wafer may be doped with p-type dopants (for example, boron (B), indium (In), aluminum (Al), or gallium (Ga)) or n-type dopants (for example, phosphorus (P) or arsenic (As)). In some embodiments, different portions of the semiconductor wafer have opposite-type dopants.

In some embodiments, the pre-processing modules 104 include a pre-treatment apparatus 108. In some embodiments, the pre-treatment apparatus 108 is a module of wafer track system 100. The pre-treatment apparatus 108 can reduce friction at the edges of the semiconductor wafer. Reducing edge friction can help prevent generating back-side edge particles when attaching the semiconductor wafer to a vacuum chuck in a subsequent processing operation that can occur, for example, in the exposure device 102. In some embodiments, the pre-treatment apparatus 108 is configured to deliver one or more gases to treat top or bottom surfaces of the semiconductor wafer. In some embodiments, the pre-treatment apparatus 108 is a cooling adhesion processing station (CADH) which applies an adhesion promoter to the top surface of the semiconductor wafer. In some embodiments, the pre-treatment apparatus 108 treats a top edge and/or a bottom edge of the semiconductor wafer to reduce edge friction of the semiconductor wafer. In some embodiments, the pre-treatment apparatus 108 serves multiple functions. The pre-treatment apparatus 108 is used to apply an adhesion promoter to a top surface of the semiconductor wafer while also treating the back side edges of the semiconductor wafer in some embodiments.

In some embodiments, the pre-processing modules 104 further include a coating module 110. For example, a photoresist layer is applied by the coating module 110 to the semiconductor wafer as a viscous liquid polymer that can be dispensed at the semiconductor wafer center and spun to distribute the photoresist layer evenly over the semiconductor wafer surface.

In some embodiments, the pre-processing modules 104 further include a soft bake process module 112. The photoresist layer may contain a significant amount of solvent after the coating operation. In some embodiments, the soft bake process module 112 is configured to perform a soft bake operation to remove solvents from the photoresist layer. The soft bake operation may be performed in a temperature range from about 80 ° C. to about 120 ° C. in some embodiments, and from about 95 ° C. to about 105 ° C. in other embodiments.

In some embodiments, the pre-processing modules 104 further include a wafer edge exposure (WEE) module 114. In some embodiments, the wafer edge exposure module 114 is configured to perform a wafer edge exposure operation to define the edge of the semiconductor wafer by exposing the photoresist mask layer at or near the edge of the wafer.

In some embodiments, the pre-processing modules 104 further include a backside treatment (BST) module 116. In some embodiments, the backside treatment module 116 includes a brush element configured to contact and clean the backside of the semiconductor wafer.

In some embodiments, the semiconductor wafer is ready for the exposure device 102 after going through the pre-processing modules 104. In some embodiments, the exposure device 102 is a stepper or a scanner that exposes the photoresist layer on a top surface of the semiconductor wafer to an energy source. In some examples, the exposure device 102 uses light in the visible, ultraviolet, deep ultraviolet, extreme ultraviolet, or other suitable spectrum wavelengths to expose the photoresist layer. In some examples, the exposure device 102 uses an electron beam, or any other suitable techniques, to execute the exposure operation to create a photoresist mask pattern on the semiconductor wafer.

In some embodiments, the post-processing modules 106 include a post-immersion rinse (PIR) module 118. In some embodiments, the post-immersion rinse module 118 performs a post-immersion rinse operation to clean the semiconductor wafer after the exposure operation is performed by the exposure device 102. For example, the post-immersion rinse operation is configured to eliminate any remaining water droplets on the surface of the photoresist mask pattern while concurrently cleaning the wafer backside to minimize the likelihood of pattern defects and contamination of subsequent modules.

In some embodiments, the post-processing modules 106 further include a post-exposure bake (PEB) module 120. In some embodiments, the post-exposure bake module 120 performs a post-exposure baking operation on the semiconductor wafer. For example, during the post-exposure baking operation, the semiconductor wafer is heated at an elevated temperature. The post-exposure baking operation may be conducted on a hotplate, in an oven, and/or with other suitable devices. In some embodiments, the temperature of the PEB is in a temperature range from about 80 ° C. to about 150 ° C., and in other embodiments, in a temperature range from 95 ° C. to 105 ° C., for a time duration ranging from about 30 seconds to about 90 seconds. The photoresist layer is chemically divided into a soluble area and an insoluble area after the post-exposure baking operation.

In some embodiments, the post-processing modules 106 further include a development module 122. In some embodiments, the development module 122 performs a development operation to transform the latent image into a tangible pattern on the semiconductor wafer.

In some embodiments, the post-processing modules 106 further include a post-development bake module 124. In some embodiments, the post-development bake module 124 is configured to perform a hard bake operation, which evaporates all solvents in the photoresist mask pattern and enhances the adhesion between the photoresist mask pattern and the semiconductor wafer. In some embodiments, the temperature of the post-development bake operation is in a temperature range from about 110 ° C. to about 150 ° C.

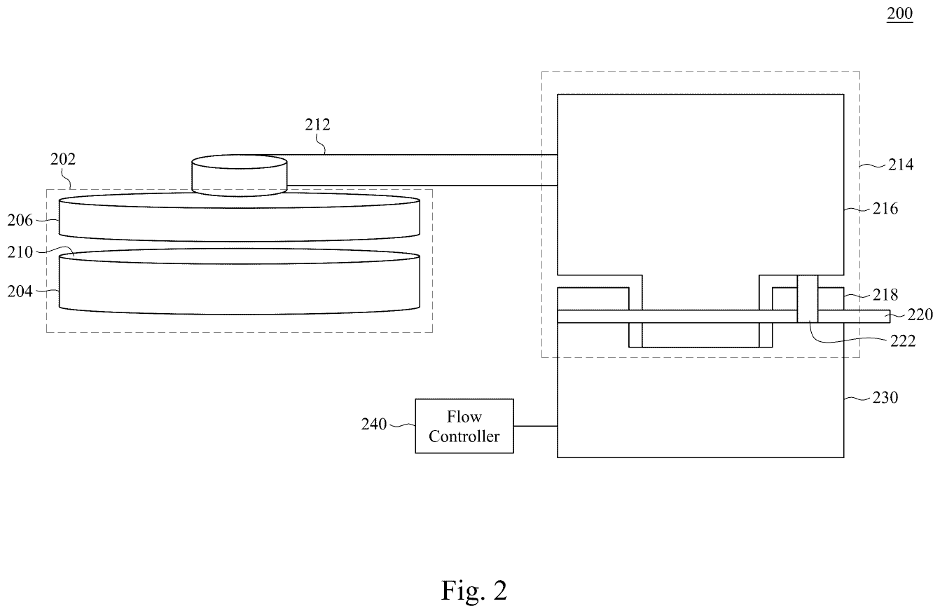

FIG. 2 illustrates an example processing apparatus 200 for an example process module, according to embodiments of the disclosure. In some embodiments, the example process module is the soft bake process module 112, the post-exposure bake module 120, or the post-development bake module 124 as shown in FIG. 1.

Although the embodiments are described with respect to illustrative examples in a specific context, namely the soft bake process module 112, the post-exposure bake module 120, and the post-development bake module 124 used in track processes, embodiments of the disclosure also include reducing contaminant particles in other track process modules where contaminant particles may be present, and the contaminant particles may subsequently interfere with other processing steps. The disclosed methods and apparatus are not limited to the processes described herein and the illustrative examples do not limit the appended claims.

In some embodiments, as shown in FIG. 2, the processing apparatus 200 includes a hot plate 204 in a chamber 202 and a hot plate cap 206 positioned above the hot plate 204. A semiconductor substrate 210 may be placed on the hot plate 204 and configured to be heated by the hot plate 204. For example, the hot plate 204 may be set at a predetermined temperature. In some examples, the semiconductor substrate 210 is positioned between the hot plate 204 and the hot plate cap 206 to be heated. The predetermined temperature is sufficient to volatilize contaminant particles on the substrate using the hot plate. Contaminant particles left on the semiconductor substrate 210 during the track processes 104/106 or the scanning process on the exposure device 102 become volatile and the volatile contaminant particles can be extracted from the chamber 202.

In some embodiments, the hot plate 204 is positioned on a semiconductor wafer table (not shown). In some embodiments, the hot plate 204 is configured to heat and maintain the semiconductor substrate 210 at a temperature between about 80 ° C. to about 300 ° C., from 80 ° C. to about 150 ° C. in other embodiments, and from 95 ° C. to about 105 ° C. in other embodiments.

In some embodiments, the contaminant particles are residues from the solvent used during the coating operation performed in the coating module 110, the post-immersion rinse operation performed in the post-immersion rinse module, or the development operation performed in the development process module 122.

In some embodiments, the chamber 202 is coupled with an external pump line 230 through a pipe channel 212. In some embodiments, the pump speed is adjusted to provide an optimized condition, including a flow rate and a pressure for the volatile contaminant particles to be sufficiently removed from the chamber 202. In some embodiments, the pump speed is adjusted by using a flow controller/regulator 240 connected to the external pump line 230. In some examples, one end of the pipe channel 212 is connected to and/or coupled with the external pump line 230 through an adapter assembly 214. In some examples, the other end of the pipe channel 212 is connected to and/or coupled with the chamber 202.

In some embodiments, the adapter assembly 214 includes a first adapter 216, a second adapter 218, and a locking mechanism (220 and 222) to secure the first adapter 216 to the second adapter 218. The first adapter 216 may be an exhaust port connected to the pipe channel 212 and configured to exhaust the volatile contaminant particles away from the chamber 202. The second adapter 218 is an inlet port connected with the external pump line 230 configured to provide suction to draw the volatile contaminant particles from the chamber 202 to the external pump line 230.

In some embodiments, the locking mechanism includes a ring clamp 220 to hold and provide support for the second adapter 218, such that the first adapter 216 can slide into and/or couple to the second adapter 218.

In some embodiments, the locking mechanism further includes a locking pin 222 to prevent the first adapter 216 from sliding away from the second adapter 218 after the first adapter 216 slides into and/or couples to the second adapter 218.

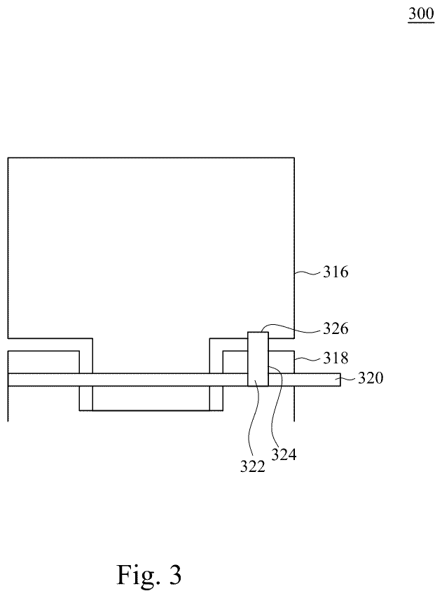

FIG. 3 illustrates a locking assembly 300 for the processing apparatus 200 in FIG. 2, according to embodiments of the disclosure.

In some embodiments, the locking assembly 300 includes a first adapter 316, a second adapter 318, and a locking mechanism (320 and 322) to secure the first adapter 316 to the second adapter 318. The first adapter 316 may be an exhaust port connected to the pipe channel 212 and configured to exhaust the volatile contaminant particles away from the chamber 202. The second adapter 318 is an inlet port connected with the external pump line (e.g., 230 of FIG. 2), configured to provide suction to draw the volatile contaminant particles from the chamber 202 to the external pump line.

In some embodiments, the second adapter 318 is a mating port for the first adapter 316. For example, the first adapter 316 can slide into and/or couple to the second adapter 318 to provide a pathway for the volatile contaminant particles to flow to the external pump line (e.g., 230 of FIG. 2). The external pump line (e.g., 230 of FIG. 2) may be connected and/or coupled to the cleanroom heating, ventilation, and air conditioning (HVAC) systems to provide suction to the chamber 202.

In some embodiments, the locking mechanism includes a ring clamp 320 to hold and provide support for the second adapter 318, such that the first adapter 316 can slide into and/or couple to the second adapter 318.

In some embodiments, the locking mechanism further includes a locking pin 322 to prevent the first adapter 316 from sliding away from the second adapter 318 after the first adapter 316 slides into and/or couples to the second adapter 318.

In some embodiments, as shown in FIG. 3, the locking pin 322 is positioned between the first adapter 316 and the second adapter 318. The locking pin 322 may be positioned in a first groove 324 in the second adapter 318. The locking pin 322 may include a spring that urges the locking pin along an axial direction of the locking pin 322 to extend outwards toward the first adapter 316. The locking pin 322 may put mechanical stress against the first adapter 316, such that the first adapter 316 and the second adapter 318 are securely attached to each other.

In some embodiments, a second groove 326 is formed in the first adapter 316. The second groove 326 is configured to be in line with the first groove 324 when the first adapter 316 is rotated with respect to the second adapter 318, such that the locking pin 322 may urge along the axial direction into the second groove 326. In some embodiments, the locking pin 322 is configured to prevent unwanted withdrawal of the first adapter 316 from the second adapter 318.

In some embodiments, the locking pin 322 is positioned in the second groove 326 in the first adapter 316. The locking pin 322 may urge along the axial direction of the locking pin 322 to extend outwards toward the second adapter 318. The locking pin 322 may put mechanical stress against the second adapter 318, such that the second adapter 318 and the first adapter 316 are securely attached to each other.

In some embodiments, the first groove 324 is configured to be in line with the second groove 326 when the first adapter 316 is rotated with respect to the second adapter 318, such that the locking pin 322 may urge along the axial direction into the first groove 324 to prevent unwanted withdrawal of the first adapter 316 from the second adapter 318.

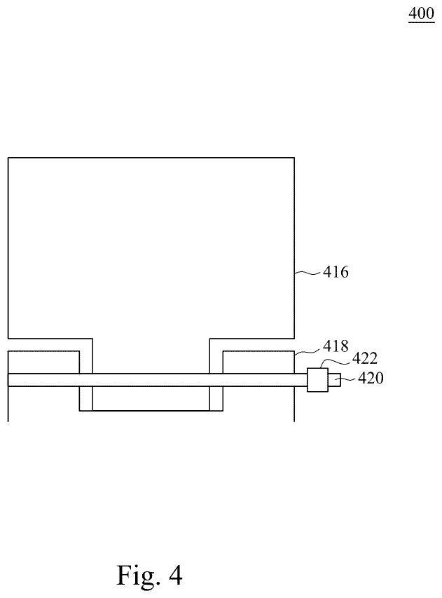

FIG. 4 illustrates a locking assembly 400 for the processing apparatus 200 in FIG. 2, according to embodiments of the disclosure.

In some embodiments, the locking assembly 400 includes a first adapter 416, a second adapter 418, and a locking mechanism (420 and 422) to secure the first adapter 416 to the second adapter 418. The first adapter 416 may be an exhaust port connected to the pipe channel 212 and configured to exhaust the volatile contaminant particles from the chamber 202. The second adapter 418 is an inlet port connected with the external pump line (e.g., 230 of FIG. 2), configured to provide suction to draw the volatile contaminant particles from the chamber 202 to the external pump line (e.g., 230 of FIG. 2).

In some embodiments, the second adapter 418 is a mating port for the first adapter 416. For example, the first adapter 416 can slide into and/or couple to the second adapter 418 to provide a pathway for the volatile contaminant particles to flow to the external pump line (e.g., 230 of FIG. 2). The external pump line (e.g., 230 of FIG. 2) may be connected and/or coupled to the cleanroom heating, ventilation, and air conditioning (HVAC) systems to provide suction to the chamber 202.

In some embodiments, the locking mechanism includes a ring clamp 420 to hold and provide support for the second adapter 418, such that the first adapter 416 can slide into and/or couple to the second adapter 418.

In some embodiments, the locking mechanism further includes a locking pin 422 to prevent the first adapter 416 from sliding away from the second adapter 418 after the first adapter 416 slides into and/or couples to the second adapter 418.

In some embodiments, as shown in FIG. 4, the locking pin 422 is positioned on the ring clamp 420. The locking pin 422 may be positioned between the second adapter 418 and the ring clamp 420. The locking pin 422 may provide mechanical stress between the second adapter 418 and the ring clamp 420, such that the second adapter 418 is pressed against and securely attached to the first adapter 416. The locking pin 422 is configured to prevent unwanted withdrawal of the first adapter 416 from the second adapter 418.

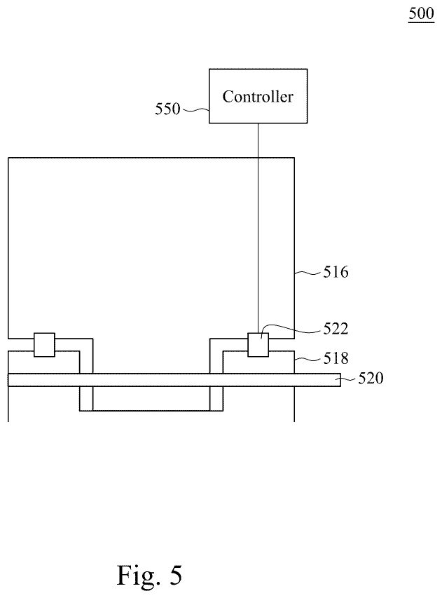

FIG. 5 illustrates a locking assembly 500 for the processing apparatus 200 in FIG. 2, according to embodiments of the disclosure.

In some embodiments, the example locking assembly 500 includes a first adapter 516, a second adapter 518, and a locking mechanism 520 to secure the first adapter 516 to the second adapter 518. The first adapter 516 may be an exhaust port connected to the pipe channel 212 and configured to exhaust the volatile contaminant particles from the chamber 202. The second adapter 518 is an inlet port connected with the external pump line (e.g., 230 of FIG. 2), configured to provide suction to draw the volatile contaminant particles from the chamber 202 to the external pump line (e.g., 230 of FIG. 2).

In some embodiments, the second adapter 518 is a mating port for the first adapter 516. For example, the first adapter 516 can slide into and/or couple to the second adapter 518 to provide a pathway for the volatile contaminant particles to flow to the external pump line (e.g., 230 of FIG. 2). The external pump line (e.g., 230 of FIG. 2) may be connected and/or coupled to the cleanroom heating, ventilation, and air conditioning (HVAC) systems to provide suction to the chamber 202.

In some embodiments, the locking mechanism includes a ring clamp 520 to hold and provide support for the second adapter 518, such that the first adapter 516 can slide into and/or couple to the second adapter 518.

In some embodiments, the locking mechanism further includes a sensor 522 to monitor and/or detect a connecting and/or coupling status between the first adapter 516 and the second adapter 518. In some embodiments, the sensor 522 senses and/or detects one or more physical parameters around the sensor 522. The sensor 522 generates sensor signals indicative of one or more parameters sensed by the sensor 522. The sensor 522 outputs the sensor signals to a controller 550.

In some embodiments, as shown in FIG. 5, the sensor 522 is positioned between the first adapter 516 and the second adapter 518.

In some embodiments, the sensor 522 is a distance sensor configured to measure a distance between the first adapter 516 and the second adapter 518. For example, if the distance between the first adapter 516 and the second adapter 518 is less than a threshold distance, the coupling between the first adapter 516 and the second adapter 518 is secured and suction is provided to draw the contaminant particles from the chamber 202 to the external pump line (e.g., 230 of FIG. 2). If the distance between the first adapter 516 and the second adapter 518 is equal to or greater than the threshold distance, the coupling between the first adapter 516 and the second adapter 518 is not secured and maintenance needs to be performed on the locking mechanism.

In some embodiments, the distance sensor is an optical sensor. In some embodiments, the distance sensor is a magnetic sensor.

In some embodiments, the sensor 522 is a stress sensor configured to measure mechanical stress between the first adapter 516 and the second adapter 518. For example, if the mechanical stress between the first adapter 516 and the second adapter 518 is equal to or greater than a threshold stress, the coupling between the first adapter 516 and the second adapter 518 is secured and suction is provided to draw the contaminant particles from the chamber to the external pump line (e.g., 230 of FIG. 2). If the mechanical stress between the first adapter 516 and the second adapter 518 is less than the threshold stress, the coupling between the first adapter 516 and the second adapter 518 is not secured and maintenance needs to be performed on the locking mechanism.

In some embodiments, maintenance on the locking mechanism includes cleaning the locking mechanism and re-engaging the first adapter 516 and the second adapter 518.

In some embodiments, the locking pin 322 in FIG. 3 and the locking pin 422 in FIG. 4 also function as sensors which work similarly to the sensor 522 in FIG. 5. The locking pin 322 in FIG. 3 and the locking pin 422 in FIG. 4 may include sensors embedded in the locking pins.

In some embodiments, the controller 550 is configured to be electrically coupled and/or connected to the sensor 522 and configured to store and compare sensor signals for evaluation, such as the coupling status between the first adapter 516 and the second adapter 518.

The controller 550 includes software and hardware for sensor signal evaluation. In one example, the controller 550 includes a media, such as a flash memory device or a hard disk, to save the sensor signals from the sensor 522. The sensor signals may be further labeled and categorized according to the associated coupling status between the first adapter 516 and the second adapter 518. In another example, the controller 550 includes an algorithm that is able to process a plurality of sensor signals associated with the coupling status between the first adapter 516 and the second adapter 518, to compare the sensor signals for a difference and to evaluate the difference for various coupling status between the first adapter 516 and the second adapter 518.

It is understood that the controller 550 may be concentrated at a single location or distributed. In one embodiment, the controller 550 is integrated in the processing apparatus 200. In another embodiment, the controller 550 is remotely connected to the processing apparatus 200 through the internet, intranet or other data communication mechanism. In yet another embodiment, the controller 550 is distributed among a plurality of processing apparatuses and shared by the plurality of processing apparatuses. In yet another embodiment, the controller 550 is a portion of a semiconductor device manufacturing system and is coupled to the processing apparatus through a suitable data communication mechanism.

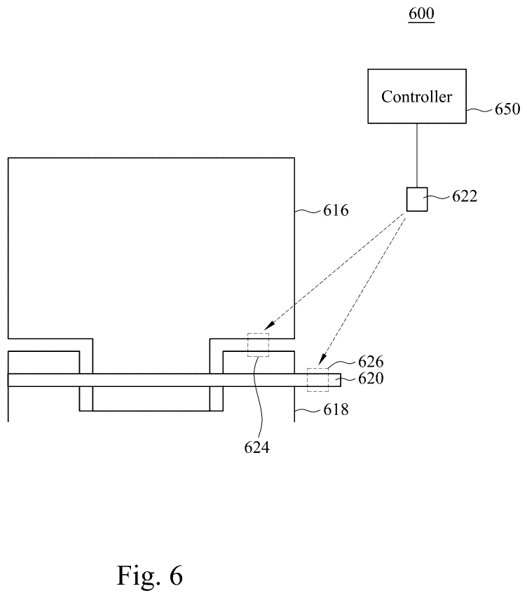

FIG. 6 illustrates a locking assembly 600 for the processing apparatus 200 in FIG. 2, according to embodiments of the disclosure.

In some embodiments, the locking assembly 600 includes a first adapter 616, a second adapter 618, and a locking mechanism (624 and 626) to secure the first adapter 616 to the second adapter 618. The first adapter 616 may be an exhaust port connected to the pipe channel 212 and configured to exhaust the volatile contaminant particles from the chamber 202. The second adapter 618 is an inlet port connected with the external pump line (e.g., 230 of FIG. 2), configured to provide suction to draw the volatile contaminant particles from the chamber 202 to the external pump line (e.g., 230 of FIG. 2).

In some embodiments, the second adapter 618 is a mating port for the first adapter 616. For example, the first adapter 616 can slide into and/or couple to the second adapter 618 to provide a pathway for the volatile contaminant particles to flow to the external pump line (e.g., 230 of FIG. 2). The external pump line (e.g., 230 of FIG. 2) may be connected and/or coupled to the cleanroom heating, ventilation, and air conditioning (HVAC) systems to provide suction to the chamber 202.

In some embodiments, the locking mechanism includes a ring clamp 620 to hold and provide support for the second adapter 618, such that the first adapter 616 can slide into and/or couple to the second adapter 618.

In some embodiments, the locking mechanism further includes an imager 622 to monitor and/or detect a connecting and/or coupling status between the first adapter 616 and the second adapter 618. For example, the imager 622 is configured to capture an image of the locking mechanism.

In some embodiments, the imager 622 is configured to monitor a position of the first adapter 616 relative to the second adapter 618 based on the captured image of the locking mechanism. For example, if the position of the first adapter is a locking position, the coupling between the first adapter 616 and the second adapter 618 is secured and suction is provided to draw the volatile contaminant particles from the chamber to the external pump line (e.g., 230 of FIG. 2). On the other hand, if the position of the first adapter is a disengaged position, the coupling between the first adapter 616 and the second adapter 618 is not secured and maintenance needs to be performed on the locking mechanism.

In some embodiments, maintenance on the locking mechanism includes cleaning the locking mechanism and re-engaging the first adapter 616 and the second adapter 618.

In some embodiments, as shown in FIG. 6, the imager 622 is secured on a side of the locking assembly 600 and positioned close to the locking mechanism (624 and 626).

In some embodiments, a controller 650 is configured to be coupled to the imager 622 and store and compare images of the locking mechanism for evaluation, such as the coupling status between the first adapter 616 and the second adapter 618.

The controller 650 includes software and hardware for image storage, image comparison, and image evaluation. In one example, the controller 650 includes a media, such as flash memory device or hard disk, to save the images of the locking mechanism from the imager 622. The images may be further labeled and categorized according to the associated coupling status between the first adapter 616 and the second adapter 618. In another embodiment, the controller 650 includes an algorithm that processes a plurality of images associated with the coupling status between the first adapter 616 and the second adapter 618, to compare the images for a difference and to evaluate the difference for various coupling statuses between the first adapter 616 and the second adapter 618.

It is understood that the controller 650 may be concentrated at a single location or distributed. In one embodiment, the controller 650 is embedded in the processing apparatus 200. In another embodiment, the controller 650 is remotely connected to the processing apparatus 200 through the internet, intranet, or other data communication mechanism. In yet another embodiment, the controller 650 is distributed among a plurality of processing apparatuses and shared by the plurality of processing apparatuses. In yet another embodiment, the controller 650 is a portion of a semiconductor device manufacturing system and is coupled to the processing apparatus through a suitable data communication mechanism.

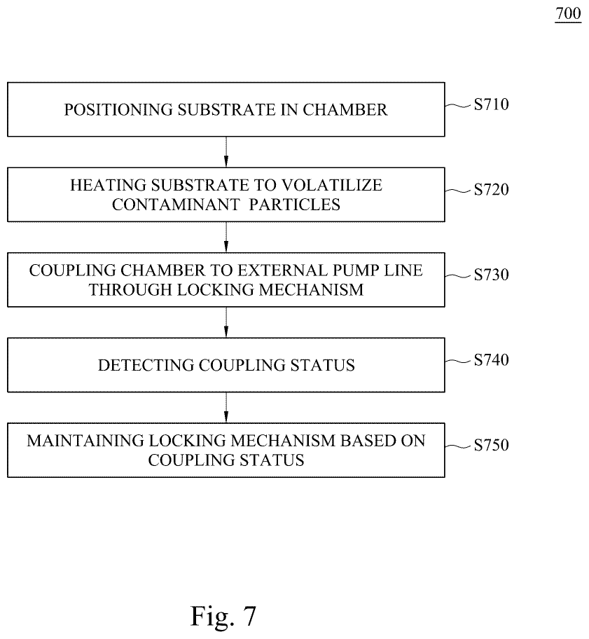

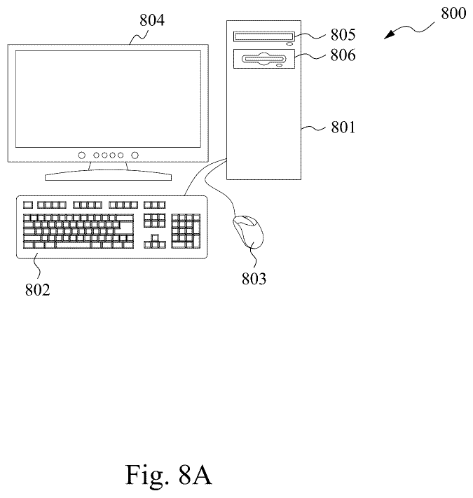

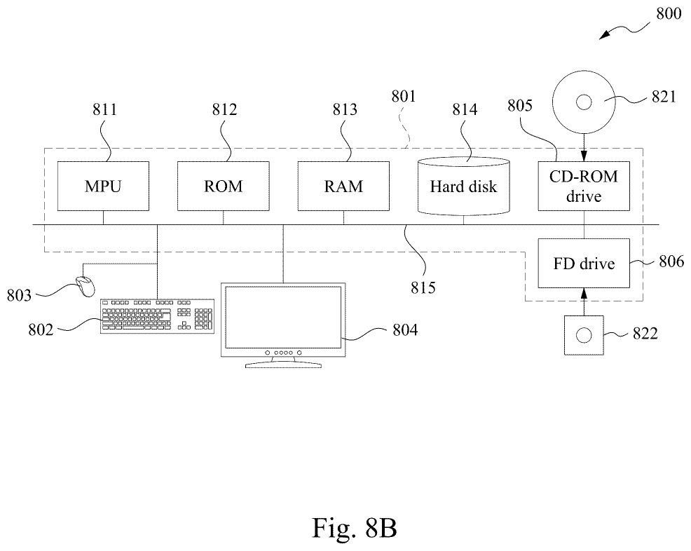

FIG. 7 illustrates a flow diagram of a process 700 for manufacturing a semiconductor device according to embodiments of the disclosure. The process 700 or a portion of the process 700 may be performed by the controller (e.g., 550 of FIGS. 5 and 650 of FIG. 6). In some embodiments, the process 700 or a portion of the process 700 is performed and/or is controlled by a computer system 800 described below with respect to FIGS. 8A and 8B.

In some embodiments, the method includes an operation S710. In operation S710, a semiconductor substrate 210 is positioned between a hot plate 204 and a hot plate cap 206 of the hot plate 204 in a chamber 202, as shown in FIG. 2.

In some embodiments, the method includes an operation S720. In operation S720, the semiconductor substrate is heated at a temperature to volatilize contaminant particles on the semiconductor substrate 210.

In some embodiments, the method includes an operation S730. In operation S730, the chamber 202 is coupled to an external pump line through a locking mechanism (e.g., 320 and 322 of FIGS. 3, 420 and 422 of FIGS. 4, 520 and 522 of FIG. 5, or 620 and 622 of FIG. 6).

In some embodiments, the locking mechanism includes a ring clamp (e.g., 220 of FIG. 2) to secure the first adapter (e.g., 216 of FIG. 2) to the second adapter (e.g., 218 of FIG. 2).

In some embodiments, the locking mechanism further includes a locking pin (e.g., 222 of FIG. 2) configured to prevent the first adapter (e.g., 216 of FIG. 2) from being separated from the second adapter (e.g., 218 of FIG. 2).

In some embodiments, the method includes an operation S740. In operation S740, a sensor (e.g., 522 of FIGS. 5 and 622 of FIG. 6) is provided to detect a coupling status between the first adapter and the second adapter.

In some embodiments, the method includes an operation S750. In operation S750, maintenance is performed on the locking mechanism based on the coupling status.

In some embodiments, the sensor (e.g., 522 of FIG. 5) is a distance sensor configured to measure a distance between the first adapter 516 and the second adapter 518. For example, if the distance between the first adapter 516 and the second adapter 518 is less than a threshold distance, the coupling between the first adapter 516 and the second adapter 518 is secured and suction is provided to draw the volatile contaminant particles from the chamber 202 to the external pump line (e.g., 230 of FIG. 2). If the distance between the first adapter 516 and the second adapter 518 is equal to or greater than the threshold distance, the coupling between the first adapter 516 and the second adapter 518 is not secured and maintenance needs to be performed on the locking mechanism.

In some embodiments, the sensor (e.g., 522 of FIG. 5) is a stress sensor to measure mechanical stress between the first adapter 516 and the second adapter 518. For example, if the mechanical stress between the first adapter 516 and the second adapter 518 is equal to or greater than a threshold stress, the coupling between the first adapter 516 and the second adapter 518 is secured and suction is provided to draw the volatile contaminant particles from the chamber to an external pump line (e.g., 230 of FIG. 2). If the mechanical stress between the first adapter 516 and the second adapter 518 is less than the threshold stress, the coupling between the first adapter 516 and the second adapter 518 is not secured and maintenance needs to be performed on the locking mechanism.

In some embodiments, the sensor is an imager 622 as shown in FIG. 6. The imager 622 may be configured to monitor a position of the first adapter 616 relative to the second adapter 618 based on the captured image of the locking mechanism. For example, if the position of the first adapter is a locking position, the coupling between the first adapter 616 and the second adapter 618 is secured and suction is provided to draw the volatile contaminant particles from the chamber to the external pump line (e.g., 230 of FIG. 2). For example, if the position of the first adapter is a disengaged position, the coupling between the first adapter 616 and the second adapter 618 is not secured and maintenance needs to be performed on the locking mechanism.

FIGS. 8A and 8B illustrate a computer system 800 for controlling the methods according to embodiments of the disclosure. In some embodiments, the computer system 800 is used for performing the functions of the controller (e.g., 550 of FIGS. 5 and 650 of FIG. 6). In some embodiments, the computer system 800 is used to execute the process 700 of FIG. 7. All of or a part of the processes, method and/or operations of the foregoing embodiments can be realized using computer hardware and computer programs executed thereon.

FIG. 8A is a diagram showing an external configuration of the computer system 800. In FIG. 8A, a computer system 800 is provided with a computer 801 including an optical disk read only memory (e.g., CD-ROM or DVD-ROM) drive 805 and a magnetic disk drive 806, a keyboard 802, a mouse 803, and a monitor 804.

FIG. 8B is a diagram showing an internal configuration of the computer system 800. In FIG. 8B, the computer 801 is provided with, in addition to the optical disk drive 805 and the magnetic disk drive 806, one or more processors, such as a micro processing unit (MPU) 811, a ROM 812 in which a program such as a boot up program is stored, a random access memory (RAM) 813 that is connected to the MPU 811 and in which a command of an application program is temporarily stored and a temporary storage area is provided, a hard disk 814 in which an application program, a system program, and data are stored, and a bus 815 that connects the MPU 811, the ROM 812, and the like. Note that the computer 801 may include a network card (not shown) for providing a connection to a LAN.

The program for causing the computer system 800 to execute the functions for the processing apparatus 200 and for manufacturing a semiconductor device in the foregoing embodiments may be stored in an optical disk 821 or a magnetic disk 822, which are inserted into the optical disk drive 805 or the magnetic disk drive 806, and transmitted to the hard disk 814. Alternatively, the program may be transmitted via a network (not shown) to the computer 801 and stored in the hard disk 814. At the time of execution, the program is loaded into the RAM 813. The program may be loaded from the optical disk 821 or the magnetic disk 822, or directly from a network. The program does not necessarily have to include, for example, an operating system (OS) or a third-party program to cause the computer 801 to execute the functions of the control system for coupling the example processing apparatus 200 in the foregoing embodiments. The program may only include a command portion to call an appropriate function (module) in a controlled mode and obtain desired results.

The novel processing apparatus and the manufacturing methods according to the present disclosure provide an improved processing apparatus and methods of coupling the same thereby reducing the maintenance of the processing apparatus and preventing withdrawal of the coupling than conventional techniques and configurations. Embodiments of the disclosure provide an improved locking mechanism that improves the tolerance to the vibrations of the processing apparatus. Consequently, efficiency of the photolithographic process can be improved for manufacturing the semiconductor devices.

An embodiment of the disclosure is a method of manufacturing a semiconductor device including positioning a substrate on a hot plate in a chamber, and heating the substrate on the hot plate to volatilize contaminant particles on the substrate. The method further includes coupling the chamber to an external pump line through a locking mechanism. The locking mechanism is configured to couple a first adapter connecting to the chamber with a second adapter connecting to the external pump line. The method also includes detecting a coupling status between the first adapter and the second adapter using a sensor, and maintaining the locking mechanism based on the coupling status. In an embodiment, the locking mechanism includes a ring clamp to secure the first adapter to the second adapter. In an embodiment, the locking mechanism further includes a locking pin to prevent withdrawal of the first adapter from the second adapter. In an embodiment, the sensor is a distance sensor configured to measure a distance between the first adapter and the second adapter. In an embodiment, the method further includes providing suction to draw the volatilized contaminant particles from the chamber to the external pump line when the distance is less than a threshold distance, and performing maintenance on the locking mechanism when the distance is equal to or greater than the threshold distance. In an embodiment, the sensor is a stress sensor configured to measure a stress between the first adapter and the second adapter. In an embodiment, the method further includes providing suction to draw the volatilized contaminant particles from the chamber to the external pump line when the stress is equal to or greater than a threshold stress, and performing maintenance on the locking mechanism when the stress is less than the threshold stress. In an embodiment, the sensor is an image sensor configured to monitor a position of the first adapter relative to the second adapter. In an embodiment, the method further includes providing suction to draw the volatilized contaminant particles from the chamber to the external pump line when the first adapter is in a locking position, and performing maintenance on the locking mechanism when the first adapter is in a disengaged position.

Another embodiment of the disclosure is a method of manufacturing a semiconductor device including positioning a substrate between a hot plate and a hot plate cap in a chamber, and heating the substrate to a temperature sufficient to volatilize contaminant particles on the substrate using the hot plate. The method further includes coupling the chamber to an external pump line through a locking mechanism. The locking mechanism is configured to couple a first adapter connecting to the chamber with a second adapter connecting to the external pump line. The locking mechanism includes a ring clamp to secure the first adapter to the second adapter and a locking pin to prevent withdrawal of the first adapter from the second adapter. In an embodiment, the method further includes detecting a coupling status between the first adapter and the second adapter using a sensor. In an embodiment, the sensor is a distance sensor configured to measure a distance between the first adapter and the second adapter. In an embodiment, the method further includes providing suction to draw the volatilized contaminant particles from the chamber to the external pump line when the distance is less than a threshold distance, and performing maintenance on the locking mechanism when the distance is equal to or greater than the threshold distance. In an embodiment, the sensor is a stress sensor configured to measure a stress between the first adapter and the second adapter. In an embodiment, the method further includes providing suction to draw the volatilized contaminant particles from the chamber to the external pump line when the stress is equal to or greater than a threshold stress, and performing maintenance on the locking mechanism when the stress is less than the threshold stress. In an embodiment, the sensor is an image sensor configured to monitor a position of the first adapter relative to the second adapter. In an embodiment, the method further includes providing suction to draw the volatilized contaminant particles from the chamber to the external pump line when the first adapter is in a locking position, and performing maintenance on the locking mechanism when the first adapter is in a disengaged position.

Another embodiment of the disclosure is a processing apparatus including a chamber and a hot plate in the chamber. The hot plate is configured to be set at a temperature to volatilize contaminant particles on a substrate positioned on the hot plate. The processing apparatus further includes a locking mechanism coupling the chamber to an external pump line. The locking mechanism is configured to couple a first adapter connecting to the chamber with a second adapter connecting to the external pump line, such that suction is provided to draw the volatilized contaminant particles from the chamber to the external pump line. The processing apparatus also includes a sensor configured to detect a coupling status between the first adapter and the second adapter. In an embodiment, the locking mechanism includes a ring clamp configured to secure the first adapter to the second adapter. In an embodiment, the locking mechanism further includes a locking pin configured to prevent withdrawal of the first adapter from the second adapter.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
heating a substrate on a hot plate in a chamber to volatilize contaminant particles on the substrate;
coupling the chamber to an external pump line through a locking mechanism, wherein the locking mechanism is configured to couple a first adapter connecting to the chamber with a second adapter connecting to the external pump line;
measuring a stress between the first adapter and the second adapter; and
maintaining the locking mechanism based on the measured stress.

2. The method according to claim 1, wherein the locking mechanism includes a ring clamp to secure the first adapter to the second adapter.

3. The method according to claim 2, wherein the locking mechanism further includes a locking pin to prevent withdrawal of the first adapter from the second adapter.

4. The method according to claim 1, further comprising measuring a distance between the first adapter and the second adapter.

5. The method according to claim 4, further comprising:
providing suction to draw the volatilized contaminant particles from the chamber to the external pump line when the distance is less than a threshold distance, and
performing maintenance on the locking mechanism when the distance is equal to or greater than the threshold distance.

6. The method according to claim 1, wherein the stress is a mechanical stress between the first adapter and the second adapter and is measured by a stress sensor.

7. The method according to claim 6, further comprising:
providing suction to draw the volatilized contaminant particles from the chamber to the external pump line when the measured stress is equal to or greater than a threshold stress, and
performing maintenance on the locking mechanism when the measured stress is less than the threshold stress.

8. The method according to claim 1, further comprising monitoring a position of the first adapter with respect to the second adapter.

9. The method according to claim 8, further comprising:
providing suction to draw the volatilized contaminant particles from the chamber to the external pump line when the first adapter is in a locked position, and
performing maintenance on the locking mechanism when the first adapter is in a disengaged position.

10. A method of manufacturing a semiconductor device, comprising:
heating a substrate in a chamber to a temperature sufficient to volatilize contaminant particles on the substrate;
coupling the chamber to an external pump line through a locking mechanism, wherein the locking mechanism is configured to couple a first adapter connecting to the chamber with a second adapter connecting to the external pump line;
monitoring, by an imager, a position of the first adapter with respect to the second adapter; and
providing suction to draw the volatilized contaminant particles from the chamber to the external pump line when the first adapter is in a locked position.

11. The method according to claim 10, further comprising detecting a distance between the first adapter and the second adapter using a sensor.

12. The method according to claim 11, wherein the distance between the first adapter and the second adapter is detected by a distance sensor.

13. The method according to claim 11, further comprising:
providing suction to draw the volatilized contaminant particles from the chamber to the external pump line when the distance is less than a threshold distance, and
performing maintenance on the locking mechanism when the distance is equal to or greater than the threshold distance.

14. The method according to claim 11, further comprising measuring a stress between the first adapter and the second adapter.

15. The method according to claim 14, further comprising:
providing suction to draw the volatilized contaminant particles from the chamber to the external pump line when the measured stress is equal to or greater than a threshold stress, and
performing maintenance on the locking mechanism when the measured stress is less than the threshold stress.

16. The method according to claim 11, further comprising:
performing maintenance on the locking mechanism when the first adapter is in a disengaged position.

17. A processing apparatus, comprising:
a hot plate in a chamber, wherein the hot plate is configured to be set at a temperature to volatilize contaminant particles on a substrate positioned on the hot plate;
a first adapter connecting with the chamber;
a second adapter configured to provide a suction pressure to draw the volatilized contaminant particles from the chamber;
a locking mechanism configured to couple the first adapter with the second adapter; and
a pump connected to the second adapter and configured to provide a suction pressure to draw the volatilized contaminant particles from the chamber.

18. The processing apparatus according to claim 17, further comprising a controller configured to:
measure a stress between the first adapter and the second adapter;
provide suction to draw the volatilized contaminant particles from the chamber when the measured stress is equal to or greater than a threshold stress; and
perform maintenance on the locking mechanism when the measured stress is less than the threshold stress.

19. The processing apparatus according to claim 17, wherein the locking mechanism includes a ring clamp configured to secure the first adapter to the second adapter.

20. The processing apparatus according to claim 19, wherein the locking mechanism further includes a locking pin configured to prevent withdrawal of the first adapter from the second adapter.
